(19) United States
(12) Patent Application Publication
(10) Pub. No.: US 2014/0122950 A1
(43) Pub. Date: May 1, 2014

(54) SEMICONDUCTOR INTEGRATED CIRCUIT DEVICE

(71) Applicant: DENSO CORPORATION, Kariya-city (JP)

(72) Inventors: Yuuki ASADA, Obu-city (JP); Naoki ITO, Nagoya-city (JP)

(73) Assignee: DENSO CORPORATION, Kariya-city (JP)

(21) Appl. No.: 14/059,796

(22) Filed: Oct. 22, 2013

(30) Foreign Application Priority Data
Oct. 30, 2012 (JP) 2012-239016
May 16, 2013 (JP) 2013-104135

(51) Int. Cl. G01R 31/3183

(52) U.S. Cl. CPC G01R 31/3183
USPC 714/726

(57) ABSTRACT

A semiconductor integrated circuit device includes first and second semiconductor chips incorporated in one package. The first semiconductor chip is subjected to a scan test. The second semiconductor chip is connected to an input-output terminal of the first semiconductor chip inside the package. The first semiconductor chip includes an input-output circuit, an output state maintaining circuit, and an input switch circuit. The input-output circuit performs input and output of data through the input-output terminal. The output state maintaining circuit maintains an output state of the input-output circuit during execution of the scan test. The input switch circuit inputs the data supplied through the input-output terminal into the input-output circuit during a normal operation. The input switch circuit inputs any data into the input-output circuit during execution of the scan test.

### CROSS REFERENCE TO RELATED APPLICATION

This application is based on Japanese Patent Application No. 2012-239016 flied on Oct. 30, 2012 and 2013-104135 filed on May 16, 2013, the contents of which are incorporated herein by reference.

### FIELD

The present disclosure relates to a semiconductor integrated circuit device including multiple semiconductor chips incorporated in one package.

### BACKGROUND

A system-in-a-package (SIP) for achieving systemization by mounting or incorporating multiple semiconductor chips in one package has the following merits. According to the SIP, chips manufactured by different types of device processes are combined in one package so that size and cost can be reduced. Further, according to the SIP, storage capacity can be easily increased by combining multiple memory devices.

As disclosed, for example, in JP-A-2005-214939 and US 2003/0057991A1 corresponding to JP-A-2003-084036, a so-called scan test has been used to test a semiconductor device, such as a microcomputer, having a variety of functions packed in one chip. In the scan test, flip-flops in a circuit are replaced with scan flip-flops having selectors. In a test mode, the scan flip-flops are serially connected to form a shift register so that a path (i.e., a scan chain) for allowing the scan flip-flops to be controlled and monitored through an external terminal of the chip can be created. Thus, since the scan flip-flops can be virtually considered as the external terminal, it is possible to detect a failure in a combinational circuit between the flip-flops. Further, since a technique to generate a test pattern for the combinational circuit is established as automatic test pattern generation (ATPG), the test pattern can be efficiently generated automatically.

### SUMMARY

However, a conventional scan test is intended for a test of a combinational circuit in one chip. Therefore, if the conventional scan test is used to test a SIP including multiple chips, the following disadvantages may occur in a test for an input-output circuit that performs an input and output of data through an input-output terminal. Since outputs of all scan flip-flops randomly change during execution of the scan test, outputs of scan flip-flops for supplying an output enable signal and output data to the input-output circuit during a normal operation randomly change accordingly. Therefore, during execution of the scan test, an output state of the input-output circuit, i.e., data (i.e., port value) outputted from the input-output circuit to the input-output terminal randomly changes. For example, the input-output terminal is connected to an input terminal or an output terminal of another chip (e.g., a custom IC) through a wire between chips.

The other chip may be subject to constraints such as prohibition of high-level (e.g., +5V) input or prohibition of low-level (e.g., 0V) input. In such a case, if the output state of the input-output circuit randomly changes during execution of the scan test, the constraints may be violated. Further, there is a possibility that high-level output or low level output occurs in the other chip. In such a case, if the output state of the input-output circuit randomly changes during execution of the scan test, outputs of the chips may collide with each other. Further, there is a need to change the port value to any value in order to test an operation of an input buffer of the input-output circuit. However, as described above, if the other chip has constraints, it is impossible to change the port value to any value. Therefore, the conventional scan test cannot be executed to test the input buffer of the input-output circuit.

In view of the above, it is an object of the present disclosure to a semiconductor integrated circuit device for allowing a scan test to be executed in a structure including multiple semiconductor chips incorporated in one package.

According to a first aspect of the present disclosure, a semiconductor integrated circuit device includes a package, a first semiconductor chip, and a second semiconductor chip. The first semiconductor chip is incorporated in the package and has an input-output terminal. The first semiconductor chip is capable of being subjected to a scan test. The second semiconductor chip is incorporated in the package and connected to the input-output terminal of the first semiconductor chip inside the package. The first semiconductor chip includes an input-output circuit, an output state maintaining circuit, and an input switch circuit. The input-output circuit performs input and output of data through the input-output terminal. The output state maintaining circuit maintains an output state of the input-output circuit during execution of the scan test. The input switch circuit inputs the data supplied through the input-output terminal into the input-output circuit during a normal operation. The input switch circuit inputs any data into the input-output circuit during execution of the scan test.

According to a second aspect of the present disclosure, a semiconductor integrated circuit device includes a package, a first semiconductor chip, and a second semiconductor chip. The first semiconductor chip is incorporated in the package and capable of being subjected to a scan test. The second semiconductor chip is incorporated in the package and has input and output terminals connected to the second semiconductor chip inside the package. The second semiconductor chip includes at least one of an input maintaining circuit and an output stop circuit. The input maintaining circuit inputs any data into an internal circuit during execution of the scan test regardless of a value of input data supplied through the input terminal from the first semiconductor chip. The output stop circuit maintains an output state of an output circuit to a high-impedance state during execution of the scan test. The output circuit is capable of outputting data through the output terminal.

### BRIEF DESCRIPTION OF THE DRAWINGS

The above and other objects, features, and advantages will become more apparent from the following description and drawings. In the drawings:

FIG. 1 is a diagram illustrating a semiconductor integrated circuit device according to a first embodiment of the present disclosure;

FIG. 2 is a diagram illustrating a semiconductor integrated circuit device according to a second embodiment of the present disclosure;

FIG. 3 is a diagram illustrating a semiconductor integrated circuit device according to a third embodiment of the present disclosure;

FIG. 4 is a diagram illustrating a semiconductor integrated circuit device according to a fourth embodiment of the present disclosure;

FIG. 5 is a diagram illustrating a semiconductor integrated circuit device according to a fifth embodiment of the present disclosure;

FIG. 6 is a diagram illustrating a semiconductor integrated circuit device according to a sixth embodiment of the present disclosure; and

FIG. 7 is a diagram illustrating a semiconductor integrated circuit device according to a seventh embodiment of the present disclosure.

### DETAILED DESCRIPTION

Embodiments of the present disclosure are described below with reference to the drawings in which like reference numerals depict like elements.

### First Embodiment

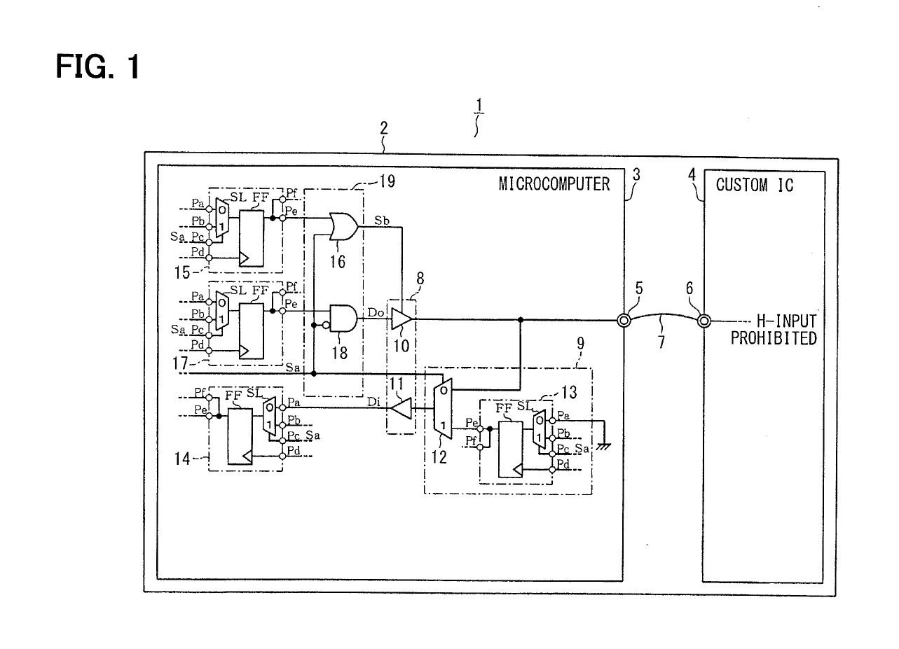

A semiconductor integrated circuit device 1 according to a first embodiment of the present disclosure is described below with reference to FIG. 1. The semiconductor integrated circuit device is configured as a system-in-a-package and includes multiple semiconductor chips incorporated in one package 2. It is noted that FIG. 1 depicts only a main portion of the semiconductor integrated circuit device 1 related to the present disclosure.

The semiconductor integrated circuit device 1 includes a semiconductor chip 3 and a semiconductor chip 4. The semiconductor chip 3 is configured as a microcomputer having a central processing unit (CPU), a read only-memory (ROM), and a random access memory (RAM) as a basic structure. The semiconductor chip 4 is configured as a custom IC for achieving various types of functions desired by a user. An input-output terminal 5 of the semiconductor chip 3 and an input-output terminal 6 of the semiconductor chip 4 are connected together by an interchip wire 7 inside the package 2.

According to the first embodiment, the semiconductor chip 4 has a constraint that high-level signal input through the input-output terminal 6 is prohibited. The high-level signal is a signal indicative of a logic of “1”, and a low-level signal is a signal indicative of a logic of “0”. For example, the high-level signal can be a signal of ±5V, and the low-level signal can be a signal of 0V.

According to the first embodiment, the semiconductor chip 3 is a test-target chip to be subjected to a scan test. Therefore, flip-flops in the semiconductor chip 3 are replaced with scan registers (i.e., scan flip-flops). The scan registers are configured as shown in FIG. 1. That is, each scan register includes a selector SL and a D-type flip-flop FF.

A normal data input terminal Pa of the scan register is connected to a first input terminal (0) of the selector SL. A test data input terminal Pb of the scan register is connected to a second input terminal (1) of the selector SL. A mode switch terminal Pc of the scan register is connected to a selection control terminal of the selector SL. A clock terminal Pd of the scan register is connected to a clock terminal of the flip-flop FF. An output terminal of the selector SL is connected to an input terminal of the flip-flop FF. An output terminal of the flip-flop FF is connected to a normal data output terminal Pe and a test data output terminal Pf of the scan register.

A clock signal is inputted to the clock terminal Pd of the scan register. Test data outputted from the downstream flip-flop FF is inputted to the test data input terminal Pb of the scan register. A scan mode enable signal Sa is inputted to the mode switch terminal Pc of the scan register. The scan mode enable signal Sa is a low-level signal during a normal operation and a high-level signal during execution of the scan test where scan data is inputted and outputted.

In the scan register, whether normal data inputted to the normal data input terminal Pa is inputted to the flip-flop FF or the test data inputted to the test data input terminal Pb is inputted to the flip-flop FF is determined based on a logic of the scan mode enable signal Sa inputted to the mode switch terminal Pc. Specifically, when the scan mode enable signal Sa is a low-level signal, the normal data is inputted to the flip-flop FF. In contrast, when the scan mode enable signal Sa is a high-level signal, the test data is inputted to the flip-flop FF.

The input-output terminal 5 of the semiconductor chip 3 is connected to a corresponding input-output circuit 8 and a corresponding input switch circuit 9. The input-output circuit 8 includes an output buffer 10 and an input buffer 11. The input-output circuit 8 performs input and output of data through the input-output terminal 5 connected to the other semiconductor chip 4. Specifically, the input-output circuit 8 outputs data, which is inputted from an internal circuit (not shown), to the semiconductor chip 4 through the input-output terminal 5. Further, the input-output circuit 8 outputs data, which is inputted from the semiconductor chip 4 through the input-output terminal 5, to an internal circuit (not shown).

The input switch circuit 9 includes a selector 12 and a scan register 13. A low-level signal is inputted to a normal data input terminal Pa of a scan register 13. A normal data output terminal Pe of the scan register 13 is connected to a first input terminal (1) of the selector 12. A second input terminal (0) of the selector 12 is connected to the input-output terminal 5. The scan mode enable signal Sa is inputted to a selection control terminal of the selector 12. An output terminal of the selector 12 is inputted to an input terminal of the input buffer 11 of the input-output circuit 8. An output terminal of the input buffer 11 is connected to a normal data input terminal Pa of a scan register 14. Normal data outputted from a normal data output terminal Pe of the scan register 14 is inputted to an internal circuit (not shown). That is, input data Di outputted from the input buffer 11 is inputted to an internal circuit (not shown) through the scan register 14.

The output buffer 10 of the input-output circuit 8 is a three-state buffer. An output enable signal Sb and output data Do are inputted to the output buffer 10. An output of the output buffer 10 is placed in one of three possible states based on the output enable signal Sb and the output data Do: a low-level signal equivalent to a logic of “1”, a high-level signal equivalent to a logic of “0”, or a high-impedance state. Specifically, when the output enable signal Sb is a high-level signal, the output buffer 10 outputs a signal having the same logic as the output data Do. In contrast, when the output enable signal Sb is a low-level signal, the output of the output buffer 10 becomes a high-impedance state.

When a low-level signal is outputted from the output buffer 10, the port value at the input-output terminal 5 becomes a low-level so that an output state of the input-output circuit 8 can become a low-level output state. When a high-level signal is outputted from the output buffer 10, the port value at the input-output terminal 5 becomes a high-level so that the output state of the input-output circuit 8 becomes a high-level output state. When the output of the output buffer 10 becomes a high-impedance state, the port value at the input-output terminal 5 becomes a high-impedance so that the output state of the input-output circuit 8 becomes a high-impedance state.

A scan register 15 supplies the output enable signal Sb to the output buffer 10 during the normal operation. Normal data used to generate the output enable signal Sb is inputted from an internal circuit (not shown) to a normal data input terminal Pa of the scan register 15. Normal data outputted from the scan register 15 is inputted to a first non-inverting input terminal of an OR gate 16. The scan mode enable signal Sa is inputted to a second non-inverting input terminal of the OR gate 16. An output signal of the OR gate 16 is inputted as the output enable signal Sb to the output buffer 10.

A scan register 17 supplies the output data Do to the output buffer 10 during the normal operation. Normal data used to generate the output data Do is inputted from an internal circuit (not shown) to a normal data input terminal Pa of the scan register 17. Normal data outputted from the scan register 17 is inputted to a non-inverting input terminal of an AND gate 18. The scan mode enable signal Sa is inputted to an inverting input terminal of the AND gate 18. An output signal of the AND gate 18 is inputted as the output data Do to the output buffer 10. According to the first embodiment, the OR gate 16 and the AND gate 18 form an output state maintaining circuit 19 for maintaining the output state of the input-output circuit 8 during execution of the scan test.

Next, effects and advantages of the first embodiment are described.

The output state maintaining circuit 19 maintains the output state of the input-output circuit 8 during execution of the scan test in the following ways. The scan mode enable signal Sa becomes a high-level signal during execution of the scan test. Accordingly, the output enable signal Sb outputted from the OR gate 16 always becomes a high-level signal regardless of a logic level of the normal data supplied to the scan register 15. Further, the output date Do outputted from the AND gate 18 always becomes a low-level signal regardless of a logic level of the normal data supplied to the scan register 17. Therefore, the output buffer 10 always outputs a low-level signal during execution of the scan test.

In this way, the output state maintaining circuit 19 maintains the output state of the input-output circuit 8 to a low-level output state during execution of the scan test. Thus, the port value at the input-output terminal 5 is maintained at a low level during execution of the scan test. Therefore, according to the first embodiment, the scan test can be performed without violation of the constraint of the semiconductor chip 4.

It is noted that the output state maintaining circuit 19 does not maintain the output state of the input-output circuit 8 during the normal operation. That is, the scan mode enable signal Sa is a low-level signal during the normal operation. Accordingly, the output enable signal Sb outputted from the OR gate 16 depends on a logic level of the normal data supplied to the scan register 15. Further, the output data Do outputted from the AND gate 18 depends on a logic level of the normal data supplied to the scan register 17. Therefore, the output state maintaining circuit 19 does not interrupt an output operation of the input-output circuit 8 during the normal operation.

The input switch circuit 9 inputs test data, which is supplied to the scan register 13, into the input buffer 11 of the input-output circuit 8 during execution of the scan test. Specifically, since the scan mode enable signal Sa is a high-level signal during execution of the scan test, test data is supplied to a flip-flop FF of the scan register 13. Then, the selector 12 outputs the data, which is inputted from the scan register 13, to the input buffer 11.

In such an approach, any test data can be inputted to the input buffer 11 of the input-output circuit 8 during execution of the scan test. Thus, according to the first embodiment, the same operation as changing the port value at the input-output terminal 5 to any value can be achieved with the port value at the input-output terminal 5 maintained (i.e., without actually changing the port value) during execution of the scan test. Therefore, even when the semiconductor chip 4 has the constraint that high-level signal input is prohibited, the scan test for the input buffer 11 (input path) of the input-output circuit 8 can be performed.

It is noted that the input switch circuit 9 inputs data, which is supplied through the input-output terminal 5, into the input buffer 11 of the input-output circuit 8 during the normal operation. Specifically, since the scan mode enable signal Sa is a low-level signal during the normal operation, test data is supplied to a flip-flop FF of the scan register 13. Then, the selector 12 outputs the data, which is inputted through the input-output terminal 5, to the input buffer 11. Thus, an input operation of the input-output circuit 8 is correctly performed during the normal operation. At this time, the flip-flop FF of the scan register 13 is supplied with a low-level signal (maintained at a low level) so that malfunction due to noise of the flip-flop FF can be prevented.

As described above, according to the first embodiment, the scan test can be performed in the semiconductor integrated circuit device 1, which is configured as a system-in-a-package including multiple semiconductor chips 3 and 4 incorporated in one package 2. Further, an additional structure (i.e., the output state maintaining circuit 19 and the input switch circuit 9) to perform the scan test does not interrupt the input and output operations of the input-output circuit 8 during the normal operation.

Further, according to the first embodiment, the additional structure to correctly perform the scan test is incorporated in the semiconductor chip 3 as a test-target chip to be subjected to the scan test. The other semiconductor chip 4 connected to the semiconductor chip 3 does not have such an additional structure. It is not always true that all of semiconductor chips incorporated in a semiconductor integrated circuit device configured as a system-in-a-package are one's own products. In other words, some of semiconductor chips incorporated in a semiconductor integrated circuit configured as a system-in-a-package may be purchased from other companies. Generally, although it is relatively easy to modify a circuit configuration of a one's own semiconductor chip, it is difficult to modify a circuit configuration of a semiconductor chip purchased from another company. Therefore, the first embodiment can be suitably applied to a case where although the semiconductor chip 3 as a microcomputer is a one's own product, the semiconductor chip 4 as a custom IC is purchased from another company.

### Second Embodiment

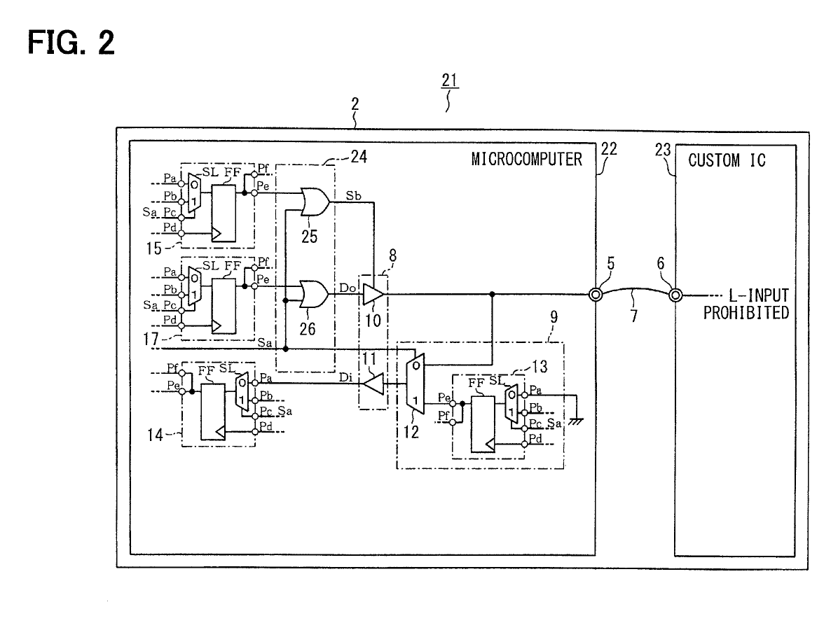

A semiconductor integrated circuit device 21 according to a second embodiment of the present disclosure is described below with reference to FIG. 2. A difference of the semiconductor integrated circuit device 21 from the semiconductor integrated circuit device 1 shown in FIG. 1 is that the semiconductor integrated circuit device 21 includes semiconductor chips 22 and 23 instead of the semiconductor chips 3 and 4.

A difference of the semiconductor chip 23 from the semiconductor chip 4 is that the semiconductor chip 23 has a constraint that low-level signal input through the input-output terminal 6 is prohibited.

A difference of the semiconductor chip 22 from the semiconductor chip 3 is that the semiconductor chip 22 includes an output state maintaining circuit 24 instead of the output state maintaining circuit 19. The output state maintaining circuit 24 has two OR gates 25 and 26. Normal data outputted from the scan register 15 is supplied to a first non-inverting input terminal of the OR gate 25. The scan mode enable signal Sa is supplied to a second non-inverting input terminal of the OR gate 25. An output signal of the OR gate 25 is supplied as the output enable signal Sb to the output buffer 10.

Normal data outputted from the scan register 17 is supplied to a first non-inverting input terminal of an OR gate 26. The scan mode enable signal Sa is supplied to a second non-inverting input terminal of the OR gate 26. An output signal of the OR gate 26 is supplied as the output data Do to the output buffer 10.

Next, effects and advantages of the second embodiment are described.

The output state maintaining circuit 24 maintains the output state of the input-output circuit 8 during execution of the scan test in the following ways. The scan mode enable signal Sa becomes a high-level signal during execution of the scan test. Accordingly, the output enable signal Sb outputted from the OR gate 25 always becomes a high-level signal regardless of a logic level of the normal data supplied to the scan register 15. Further, the output date Do outputted from the OR gate 26 always becomes a high-level signal regardless of a logic level of the normal data supplied to the scan register 17. Therefore, the output buffer 10 always outputs a high-level signal during execution of the scan test.

In this way, the output state maintaining circuit 24 maintains the output state of the input-output circuit 8 to a high-level output state during execution of the scan test. Thus, the port value at the input-output terminal 5 is maintained at a high level during execution of the scan test. Therefore, according to the second embodiment, the scan test can be performed without violation of the constraint of the semiconductor chip 23 that low-level signal input is prohibited.

It is noted that the output state maintaining circuit 24 does not maintain the output state of the input-output circuit 8 during the normal operation. That is, the scan mode enable signal Sa is a low-level signal during the normal operation. Accordingly, the output enable signal Sb outputted from the OR gate 25 depends on a logic level of the normal data supplied to the scan register 15. Further, the output data Do outputted from the OR gate 26 depends on a logic level of the normal data supplied to the scan register 17. Therefore, the output state maintaining circuit 24 does not interrupt an output operation of the input-output circuit 8 during the normal operation.

As described above, the second embodiment can provide the same effect and advantage as the first embodiment. Further, like the first embodiment, the second embodiment can be suitably applied to a case where although the semiconductor chip 22 as a microcomputer is a one's own product, the semiconductor chip 23 as a custom IC is purchased from another company.

### Third Embodiment

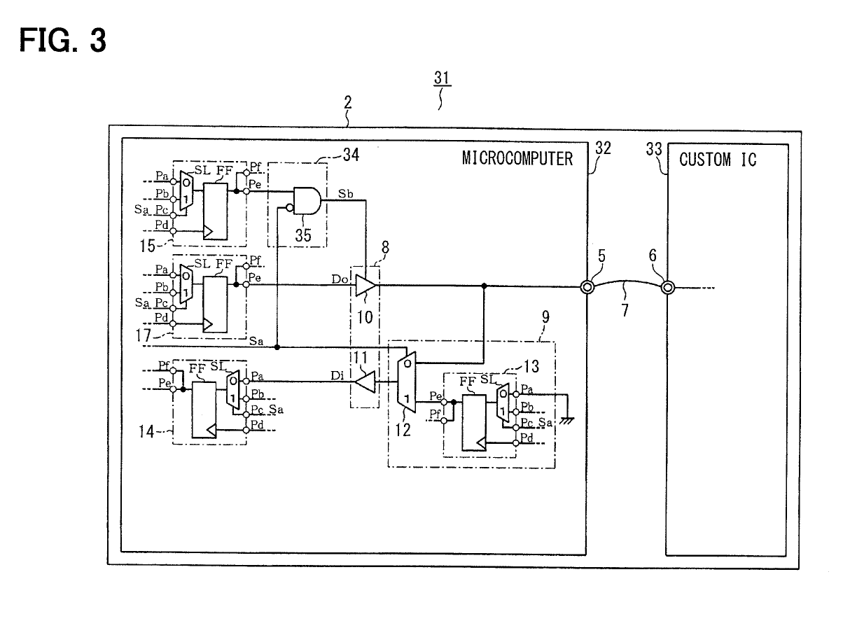

A semiconductor integrated circuit device 31 according to a third embodiment of the present disclosure is described below with reference to FIG. 3. A difference of the semiconductor integrated circuit device 31 from the semiconductor integrated circuit device 1 shown in FIG. 1 is that the semiconductor integrated circuit device 31 includes semiconductor chips 32 and 33 instead of the semiconductor chips 3 and 4. A difference of the semiconductor chip 33 from the semiconductor chip 4 is that the semiconductor chip 33 has no constraint on a signal inputted through the input-output terminal 6. However, there is a possibility that the input-output terminal 6 becomes a high-level output state to output a high-level signal or a low-level output state to output a low-level signal.

A difference of the semiconductor chip 32 from the semiconductor chip 3 is that the semiconductor chip 32 includes an output state maintaining circuit 34 instead of the output state maintaining circuit 19. The output state maintaining circuit 34 has an AND gate 35. Normal data outputted from the scan register 15 is supplied to a non-inverting input terminal of the AND gate 35. The scan mode enable signal Sa is supplied to an inverting input terminal of the AND gate 35. An output signal of the AND gate 35 is supplied as the output enable signal Sb to the output buffer 10. In this case, an output signal of the scan register 17 is supplied as the output data Do to the output buffer 10.

Next, effects and advantages of the third embodiment are described.

The output state maintaining circuit 34 maintains the output state of the input-output circuit 8 during execution of the scan test in the following ways. The scan mode enable signal Sa becomes a high-level signal during execution of the scan test. Accordingly, the output enable signal Sb outputted from the AND gate 35 always becomes a low-level signal regardless of a logic level of the normal data supplied to the scan register 15. Therefore, the output buffer 10 always becomes a high impedance output state during execution of the scan test.

In this way, the output state maintaining circuit 34 maintains the output state of the input-output circuit 8 to a high impedance output state during execution of the scan test. Thus, the port value at the input-output terminal 5 is maintained at high impedance during execution of the scan test. Assuming that the input-output terminal 6 of the semiconductor chip 33 is maintained to a high-level output state or a low-level output state during execution of the scan test of the semiconductor chip 32, when the port values at the input-output terminals 5 and 6 randomly change due to the operation (i.e., scan test) of the semiconductor chip 32, outputs may collide with each other. Even in such a case, according to the third embodiment, the output state maintaining circuit 34 maintains the output state of the input-output circuit 8 to a high impedance output state during execution of the scan test, thereby preventing the outputs from colliding with each other. Therefore, even when the input-output terminal 6 of the semiconductor chip 33 is maintained to a high-level output state or a low-level output state, the scan test can be executed in the semiconductor chip 32.

It is noted that the output state maintaining circuit 34 does not maintain the output state of the input-output circuit 8 during the normal operation. That is, the scan mode enable signal Sa is a low-level signal during the normal operation. Accordingly, the output enable signal Sb outputted from the AND gate 35 depends on a logic level of the normal data supplied to the scan register 15. Therefore, the output state maintaining circuit 34 does not interrupt an output operation of the input-output circuit 8 during the normal operation.

Further, like the first embodiment, the third embodiment can be suitably applied to a case where although the semiconductor chip 32 as a microcomputer is a one's own product, the semiconductor chip 33 as a custom IC is purchased from another company.

### Fourth Embodiment

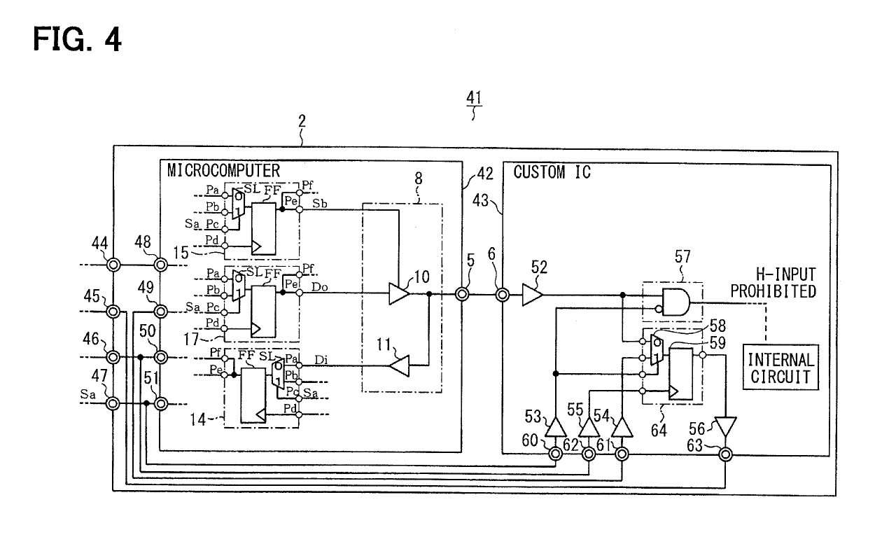

A semiconductor integrated circuit device 41 according to a fourth embodiment of the present disclosure is described below with reference to FIG. 4. A difference of the semiconductor integrated circuit device 41 from the semiconductor integrated circuit device 1 shown in FIG. 1 is that the semiconductor integrated circuit device 41 includes semiconductor chips 42 and 43 instead of the semiconductor chips 3 and 4. It is noted that FIG. 4 depicts terminals which are omitted in FIG. 1.

The package 2 has external terminals 44-47 exposed outside the package 2. The external terminal 44 is used to input the test data for the scan test from outside at the time of scan data in. The external terminal 45 is used to monitor a state of the scan register from outside at the time of scan data out. The external terminal 46 is used to input the clock signal. The external terminal 47 is used to input the scan mode enable signal Sa from outside.

A difference of the semiconductor chip 42 from the semiconductor chip 3 is that the semiconductor chip 42 does not have the input switch circuit 9 and the output state maintaining circuit 19. In this case, the input-output-terminal 5 is connected to the output terminal of the output buffer 10 and the input terminal of the input buffer 11 of the input-output circuit 8. Further, the output enable signal Sb is supplied to the output buffer 10 directly from the scan register 15, and the output data Do is supplied to the output buffer 10 directly from the scan register 17.

A terminal 48 is connected to the external terminal 44. Although not shown in FIG. 4, the terminal 48 is connected to the test data input terminal Pb of the most upstream scan register of all the scan registers in the semiconductor chip 42. A terminal 49 is connected to the semiconductor chip 43. Although not shown in FIG. 4, the terminal 49 is connected to the test data output terminal Pf of the most downstream scan register of all the scan registers in the semiconductor chip 42. A terminal 50 is connected to the external terminal 46. Although not shown in FIG. 4, the terminal 50 is connected to the clock terminals Pb of the scan registers in the semiconductor chip 42. A terminal 51 is connected to the external terminal 47 and the mode switch terminals Pc of the scan registers in the semiconductor chip 42.

A difference of the semiconductor chip 43 from the semiconductor chip 4 is that the semiconductor chip 43 further includes buffers 52-56, an input maintaining circuit 57, a selector 58, and a D-type flip-flop 59. The input maintaining circuit 57 has an AND gate. The input-output terminal 6 is connected to a non-inverting input terminal of the input maintaining circuit 57 through the buffer 52. A terminal 60 is connected to the external terminal 47 and also connected to an inverting input terminal of the input maintaining circuit 57 through the buffer 53. An output of the input maintaining circuit 57 is supplied to an internal circuit (not shown).

In such a structure, input data supplied from the semiconductor chip 42 through the input-output terminal 6 is supplied to the internal circuit during a time period where the scan mode enable signal Sa is at a low level. Further, low-level data is supplied to the internal circuit regardless of a value of the input data during a time period where the scan mode enable signal Sa is at a high level.

The input-output terminal 6 is connected to a first input terminal (0) of the selector 58 through the buffer 52. The terminal 60 is also connected to a selection control terminal of the selector 58 through the buffer 53. A terminal 61 is connected to the terminal 49 of the semiconductor chip 42 and also connected to a second input terminal (1) of the selector 58 through the buffer 54. An output terminal of the selector 58 is connected to an input terminal of the flip-flop 59.

A terminal 62 is connected to the external terminal 46 and also connected to a clock terminal of the flip-flop 59. An output terminal of the flip-flop 59 is connected to a terminal 63 through the buffer 56. The terminal 63 is connected to the external terminal 45. According to the fourth embodiment, the selector 58 and the flip-flop 59 form an input monitor circuit 64.

In such a structure, input data (i.e., port value) supplied from the semiconductor chip 42 through the input-output terminal 6 is held by the flip-flop 59. The input monitor circuit 64 including the flip-flop 59 is connected to a scan chain which is formed at the time of the scan test. Thus, input data supplied from the semiconductor chip 42 can be monitored through the external terminal 45 which is used to monitor a state of the scan register at the time of the scan test.

As described above, according to the fourth embodiment, the scan mode enable signal Sa is at a high level during execution of the scan test so that the input maintaining circuit 57 can supply low-level data to the internal circuit regardless of a value of input data supplied from the semiconductor chip 42. Thus, the scan test can be performed without violation of the constraint of the semiconductor chip 43 that high-level signal input is prohibited. Further, the input monitor circuit 64 allows input data, which is supplied from the semiconductor chip 42 through the input-output terminal 6 during execution of the scan test, to be monitored from outside through a scan chain formed at the time of the scan test. Thus, a connection between the semiconductor chips 42 and 43 can be tested without adding external terminals exposed outside the package 2.

Further, according to the fourth embodiment, an additional structure to correctly perform the scan test is incorporated in the other semiconductor chip 43, not the semiconductor chip 42 as a test-target chip to be subjected to the scan test. The semiconductor chip 42 does not have such an additional structure. Therefore, the fourth embodiment can be suitably applied to a case where although the semiconductor chip 43 as a custom IC is a one's own product, the semiconductor chip 42 as a microcomputer is purchased from another company.

### Fifth Embodiment

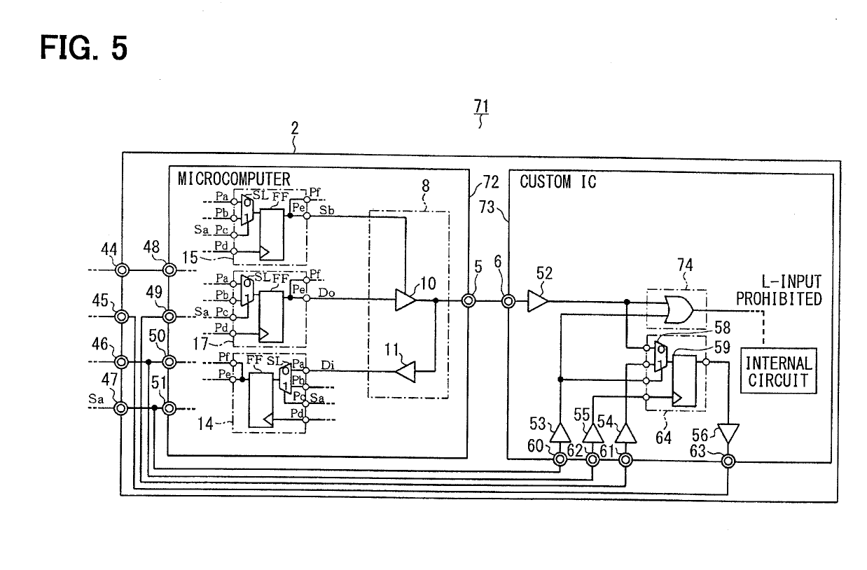

A semiconductor integrated circuit device 71 according to a fifth embodiment of the present disclosure is described below with reference to FIG. 5. A difference of the semiconductor integrated circuit device 71 from the semiconductor integrated circuit device 21 shown in FIG. 2 is that the semiconductor integrated circuit device 71 includes semiconductor chips 72 and 73 instead of the semiconductor chips 22 and 23. The semiconductor chip 72 has the same structure as the semiconductor chip 42 of the fourth embodiment.

A difference of the semiconductor chip 73 from the semiconductor chip 23 is that the semiconductor chip 73 further includes buffers 52-56, an input maintaining circuit 74, a selector 58, and a flip-flop 59. The input maintaining circuit 74 has an OR gate. The input-output terminal 6 is connected to a first input terminal of the input maintaining circuit 74 through the buffer 52. A terminal 60 is connected to a second input terminal of the input maintaining circuit 74 through the buffer 53. An output of the input maintaining circuit 74 is supplied to an internal circuit (not shown).

In such a structure, input data supplied from the semiconductor chip 72 through the input-output terminal 6 is supplied to the internal circuit during a time period where the scan mode enable signal Sa is at a low level. Further, high-level data is supplied to the internal circuit regardless of a value of the input data during a time period where the scan mode enable signal Sa is at a high level.

As described above, according to the fifth embodiment, the scan mode enable signal Sa is at a high level during execution of the scan test so that the input maintaining circuit 74 can supply high-level data to the internal circuit regardless of a value of input data supplied from the semiconductor chip 72. Thus, the scan test can be performed without violation of the constraint of the semiconductor chip 73 that low-level signal input is prohibited. Further, like the fourth embodiment, the selector 58 and the flip-flop 59 form an input monitor circuit 64. Thus, a connection between the semiconductor chips 72 and 73 can be tested without adding external terminals exposed outside the package 2.

Further, like the fourth embodiment, the fifth embodiment can be suitably applied to a case where although the semiconductor chip 73 as a custom IC is a one's own product, the semiconductor chip 72 as a microcomputer is purchased from another company.

### Sixth Embodiment

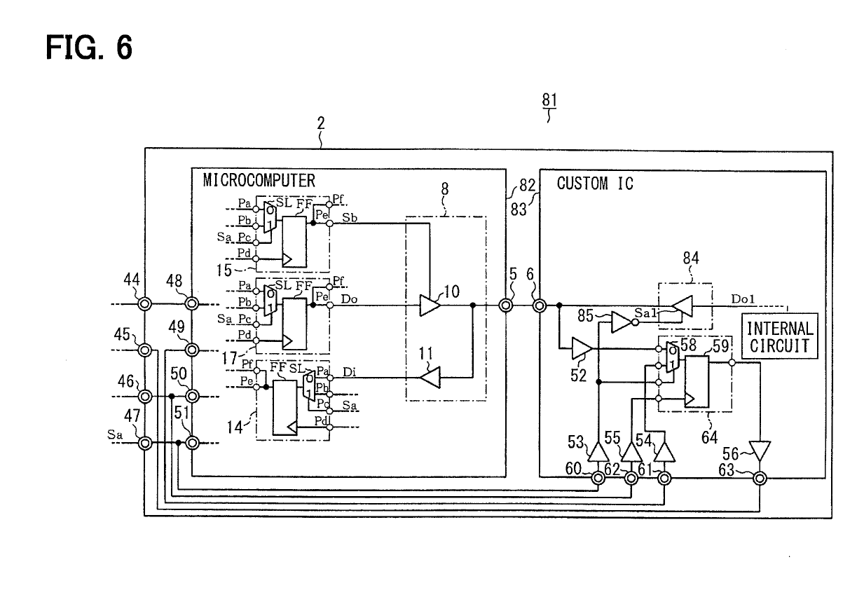

A semiconductor integrated circuit device 81 according to a sixth embodiment of the present disclosure is described below with reference to FIG. 6. A difference of the semiconductor integrated circuit device 81 from the semiconductor integrated circuit device 31 shown in FIG. 3 is that the semiconductor integrated circuit device 81 includes semiconductor chips 82 and 83 instead of the semiconductor chips 32 and 33. The semiconductor chip 82 has the same structure as the semiconductor chip 42 of the fourth embodiment.

A difference of the semiconductor chip 83 from the semiconductor chip 33 is that the semiconductor chip 83 further includes buffers 52-56, a selector 58, a flip-flop 59, an output circuit 84, and an inverter circuit 85. Further, the input-output terminal 6 of the semiconductor chip 83 always outputs a signal of a predetermined level (e.g., reset signal for a microcomputer). The input-output terminal 6 is connected to a first input terminal (0) of the selector 58 through the buffer 52 and also connected to an output terminal of the output circuit 84.

The output circuit 84 includes a three-state buffer and outputs data through the input-output terminal 6 connected to the semiconductor chip 82. An output enable signal Sa1 and output data Do1 are supplied to the output circuit 84 from an internal circuit (not shown). The inverter circuit 85 inverts the scan mode enable signal Sa, thereby producing the output enable signal Sa1. An output of the output circuit 84 is placed in one of three possible states based on the output enable signal Sa1 and the output data Do1: a low-level signal equivalent to a logic of “1”, a high-level signal equivalent to a logic of “0”, or a high-impedance state.

Specifically, when the output enable signal Sa1 is a high-level signal, the output circuit 84 outputs a signal having the same logic as the output data Do1. In contrast, when the output enable signal Sa1 is a low-level signal, the output of the output circuit 84 becomes a high-impedance state. In this way, the output circuit 84 can serve as an output stop circuit that stops an output by maintaining its output state to a high-impedance state.

As described above, according to the sixth embodiment, the scan mode enable signal Sa is at a high level during execution of the san test so that its output state can be maintained to a high-impedance state. Therefore, even when the semiconductor chip 82 as a test-target chip to be subjected to the scan test is connected to the semiconductor chip 83 which always outputs a signal of a predetermined level, the scan test can be correctly performed without collision between outputs. Further, like the fourth embodiment, the selector 58 and the flip-flop 59 form an input monitor circuit 64. Thus, a connection between the semiconductor chips 82 and 83 can be tested without adding external terminals exposed outside the package 2. Further, like the fourth embodiment, the sixth embodiment can be suitably applied to a case where although the semiconductor chip 83 as a custom IC is a one's own product, the semiconductor chip 82 as a microcomputer is purchased from another company.

### Seventh Embodiment

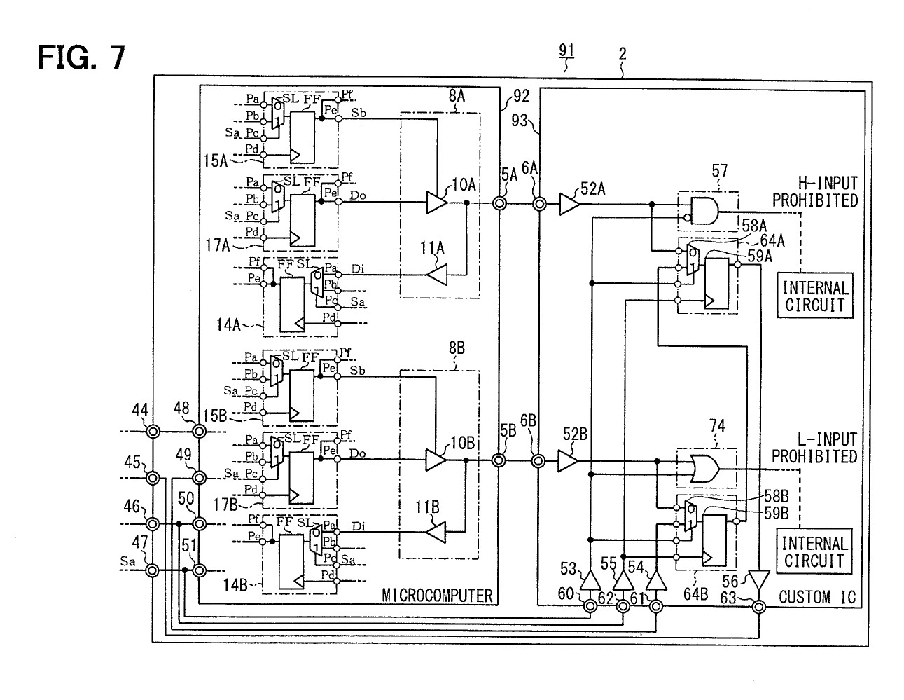

A semiconductor integrated circuit device 91 according to a seventh embodiment of the present disclosure is described below with reference to FIG. 7.

It is not always essential that the other semiconductor chip connected to the test-target chip to be subjected to the scan test includes only one of the input maintaining circuits 57 and 74 and the output circuit 84 as described in the fourth, fifth, and sixth embodiments. In other words, the other semiconductor chip can include any two or all of the input maintaining circuits 57 and 74 and the output circuit 84. In this case, the circuits to be included in the other semiconductor chip can be selected according to specifications (e.g., present or absence of constraints, and content of constrains) of the other semiconductor chip. When two or all of the input maintaining circuits 57 and 74 and the output circuit 84 are included, there is a need that multiple input monitor circuits 64 are connected to a scan chain. In the seventh embodiment, a case where both the input maintaining circuits 57 and 74 are included is described as an example.

As shown in FIG. 7, the semiconductor integrated circuit device 91 includes semiconductor chips 92 and 93. The semiconductor chip 92 is a combination of the semiconductor chips 42 and 72. That is, the semiconductor chip 92 has two input-output terminals 5A and 5B connected to the semiconductor chip 93. To distinguish elements of the semiconductor chip 92 related to the input-output terminal 5A from elements of the semiconductor chip 92 related to the input-output terminal 5B, a letter “A” is added to reference numbers of the elements related to the input-output terminal 5A, and a letter “B” is added to reference numbers of the elements related to the input-output terminal 5B.

The semiconductor chip 93 is a combination of the semiconductor chips 43 and 73. That is, the semiconductor chip 93 has two input-output terminals 6A and 6B connected to the semiconductor chip 92. To distinguish elements of the semiconductor chip 93 related to the input-output terminal 6A from elements of the semiconductor chip 93 related to the input-output terminal 6B, a letter “A” is added to reference numbers of the elements related to the input-output terminal 6A, and a letter “B” is added to reference numbers of the elements related to the input-output terminal 6B.

In this case, the terminal 61 is connected to a second input terminal (1) of a selector 58B through the buffer 54. An output terminal of a flip-flop 59B is connected to a second input terminal (1) of a selector 58A. An output terminal of a flip-flop 59A is connected to the terminal 63 through the buffer 56. Thus, input monitor circuits 64A and 64B are connected to a scan chain which is formed at the time of the scan test. Therefore, like the fourth, fifth, and sixth embodiments, a connection between the semiconductor chips 92 and 93 can be tested without adding external terminals exposed outside the package 2.

(Modifications)

While the present disclosure has been described with reference to embodiments thereof, it is to be understood that the disclosure is not limited to the embodiments. The present disclosure is intended to cover various modifications and equivalent arrangements within the spirit and scope of the present disclosure.

It is not always essential that the test-target chip to be subjected to the scan test includes only one of the output state maintaining circuits 19, 24, and 34. In other words, the test-target chip can include any two or all of the output state maintaining circuits 19, 24, and 34. In this case, the circuits to be included in the test-target chip can be selected according to specifications (e.g., present or absence of constraints, and content of constrains) of the other semiconductor chip.

A circuit configuration of the output state maintaining circuit for maintaining the output state of the input-output circuit 8 to a low-level output state during execution of the scan test is not limited to that shown in FIG. 1. A circuit configuration of the output state maintaining circuit for maintaining the output state of the input-output circuit 8 to a high-level output state during execution of the scan test is not limited to that shown in FIG. 2. A circuit configuration of the output state maintaining circuit for maintaining the output state of the input-output circuit 8 to a high-impedance state during execution of the scan test is not limited to that shown in FIG. 3. A circuit configuration of the input switch circuit for inputting data supplied through the input-output terminal 5 into the input-output circuit 8 during the normal operation and for inputting any test data into the input-output circuit 8 during execution of the scan test is not limited to that shown in FIG. 1.

A signal supplied to the normal data input terminal Pa of the scan register 13 of the input switch circuit 9 can be either a high-level signal or a low-level signal, because it is not used during the normal operation.

A circuit configuration of the input maintaining circuit for supplying low-level data to the internal circuit regardless of a value of input data supplied from the test-target chip during execution of the scan test is not limited to that shown in FIG. 4. A circuit configuration of the input maintaining circuit for supplying high-level data to the internal circuit regardless of a value of input data supplied from the test-target chip during execution of the scan test is not limited to that shown in FIG. 5. A circuit configuration of the input monitor circuit for allowing input data supplied from the test-target chip during execution of the scan test to be monitored from outside through the scan chain formed at the time of the scan test is not limited to those shown in FIGS. 4-7.

The input monitor circuit 64 of the semiconductor integrated circuit device 41, 71, 81, and 91 can be omitted if a connection test between the test-target chip and the other chip connected to the test-target chip is unnecessary.

What is claimed is:

1. A semiconductor integrated circuit device comprising:
a package;
a first semiconductor chip incorporated in the package and having an input-output terminal, the first semiconductor chip capable of being subjected to a scan test; and
a second semiconductor chip incorporated in the package and connected to the input-output terminal of the first semiconductor chip inside the package, wherein
the first semiconductor chip includes an input-output circuit, an output state maintaining circuit, and an input switch circuit,
the input-output circuit performs input and output of data through the input-output terminal,
the output state maintaining circuit maintains an output state of the input-output circuit during execution of the scan test,
the input switch circuit inputs the data supplied through the input-output terminal into the input-output circuit during a normal operation, and
the input switch circuit inputs any data into the input-output circuit during execution of the scan test.

2. The semiconductor integrated circuit device according to claim 1, wherein
the output state maintaining circuit maintains the output state of the input-output circuit to a low-level output state during execution of the scan test.

3. The semiconductor integrated circuit device according to claim 1, wherein
the output state maintaining circuit maintains the output state of the input-output circuit to a high-level output state during execution of the scan test.

4. The semiconductor integrated circuit device according to claim 1, wherein
the output state maintaining circuit maintains the output state of the input-output circuit to a high-impedance state during execution of the scan test.

5. The semiconductor integrated circuit device according to claim 1, wherein
the output state maintaining circuit maintains the output state of the input-output circuit to a low-level output state, a high-level output state, or a high-impedance state during execution of the scan test.

6. A semiconductor integrated circuit device comprising:
a package;
a first semiconductor chip incorporated in the package and capable of being subjected to a scan test; and
a second semiconductor chip incorporated in the package and having input and output terminals connected to the second semiconductor chip inside the package, wherein
the second semiconductor chip includes at least one of an input maintaining circuit and an output stop circuit,
the input maintaining circuit inputs any data into an internal circuit during execution of the scan test regardless of a value of input data supplied through the input terminal from the first semiconductor chip, and
the output stop circuit maintains an output state of an output circuit to a high-impedance state during execution of the scan test, the output circuit being capable of outputting data through the output terminal.

7. The semiconductor integrated circuit device according to claim 6, wherein
the second semiconductor chip includes an input monitor circuit capable of allowing the input data to be monitored from outside the package during execution of the scan test through a scan chain which is formed at the time of the scan test.

8. The semiconductor integrated circuit device according to claim 6, wherein
the input maintaining circuit inputs low-level data into the internal circuit during execution of the scan test regardless of the value of the input data.

9. The semiconductor integrated circuit device according to claim 6, wherein
the input maintaining circuit inputs high-level data into the internal circuit during execution of the scan test regardless of the value of the input data.

10. The semiconductor integrated circuit device according to claim 6, wherein
the input maintaining circuit inputs low-level data or high-level data into the internal circuit during execution of the scan test regardless of the value of the input data.
